(19) United States
(12) Patent Application Publication
(10) Pub. No.: US 2011/0073872 A1
(43) Pub. Date: Mar. 31, 2011

(54) HIGH BRIGHTNESS LIGHT EMITTING DIODE AND MANUFACTURING METHOD THEREOF

(75) Inventors: TZU-CHIEN HUNG, Tu-Cheng (TW); CHIA-HUI SHEN, Tu-Cheng (TW); CHIH-PANG MA, Tu-Cheng (TW)

(73) Assignee: ADVANCED OPTOELECTRONIC TECHNOLOGY, INC., Hsinchu Hsien (TW)

(21) Appl. No.: 12/862,777

(22) Filed: Aug. 25, 2010

(30) Foreign Application Priority Data
Sep. 29, 2009 (CN) 200910177380.5

(51) Int. Cl. H01L 33/02; H01L 33/12; H01L 33/00

(52) U.S. Cl. 257/77; 257/99; 438/46; 257/103; 257/E33.013; 257/E33.005

(57) ABSTRACT

A high brightness light emitting diode includes a carrier substrate and an epitaxial multi-layer formed thereon. The carrier substrate includes a metal material and a medium, and a coefficient of thermal expansion (CTE) of the medium is less than a CTE of the metal material.

### BACKGROUND

1. Technical Field

The present disclosure generally relates to light emitting diodes, and particularly to a high brightness light emitting diode with a metal substrate.

2. Description of the Related Art

Light emitting diodes (LEDs) have many advantages, such as high luminosity, low operational voltage, low power consumption, compatibility with integrated circuits, easy driving, long-term reliability, and environmental friendliness, which have promoted the LEDs as a widely used light source.

Referring to FIGS. 1 to 6, FIG. 1 and FIG. 2 are schematic views showing a commonly used light emitting diode, and FIG. 3 to FIG. 6 are schematic views of a vertical cross section of the light emitting diode. As shown in FIG. 1, a frequently used manufacturing method of a light emitting diode (LED) 100 provides a sapphire substrate 102, on which a buffer layer (not shown), an n-type semiconductor layer 104, an active layer 106, and a p-type semiconductor layer 108 are sequentially epitaxially formed.

Referring to FIG. 2, since the sapphire provides only limited thermal and electrical conductivity, in preparation of the LED 100 with a sapphire substrate 102, a partial active layer 106 and p-type semiconductor layer 108 must be removed to expose partial n-type semiconductor layer 104. The electrodes 112 and 114 are on the same side and separately formed on the p-type semiconductor layer 108 and the exposed partial n-type semiconductor layer 104.

For improving heat dissipation and uniformity of electrical distribution, an electric conductive substrate replacing the sapphire substrate 102 is used. Referring to FIG. 3, after forming the n-type semiconductor layer 104, the active layer 106, and the p-type semiconductor layer 108 on the sapphire substrate 102, FIG. 4 shows a thicker copper layer as metal substrate 110 is formed on the top surface of the p-type semiconductor layer 108. The sapphire substrate 102 is removed using laser, with enhanced thermal and electric conduction metal substrate 110 replacing the sapphire substrate 102 (as shown in FIG. 5). Referring to FIG. 6, an electrode (not shown) of the p-type semiconductor layer 108 is formed on the metal substrate 110, and another electrode 114 is formed on the n-type semiconductor layer 104. The dies are cut to obtain an isolated LED 150.

The difference of coefficient of thermal expansion (CTE) of metal and semiconductor will cause stress and damage to the LED 150. Moreover, when the metal substrate 110 is used, thickness thereof must exceed 100 μm to support the LED 150. The thickness renders cutting more difficult.

What is needed, therefore, is a light emitting diode which can prevent damage caused by stress of different CTE, and ameliorate the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the high brightness light emitting diode. Moreover, in the drawings, like reference numerals designate corresponding parts throughout the views.

FIGS. 1 and FIG. 2 are schematic views of a vertical cross section of a commonly used light emitting diode and its semi-finished product.

FIG. 3 to FIG. 6 are schematic views of a vertical cross section of another commonly used light emitting diode and its semi-finished products.

FIG. 7 to FIG. 11 are schematic views of a vertical cross section of a light emitting diode in accordance with a first embodiment of the present disclosure and its semi-finished products, wherein FIG. 7 to FIG. 10 sequentially represent the semi-finished products at different manufacturing steps and FIG. 11 represents the finished product.

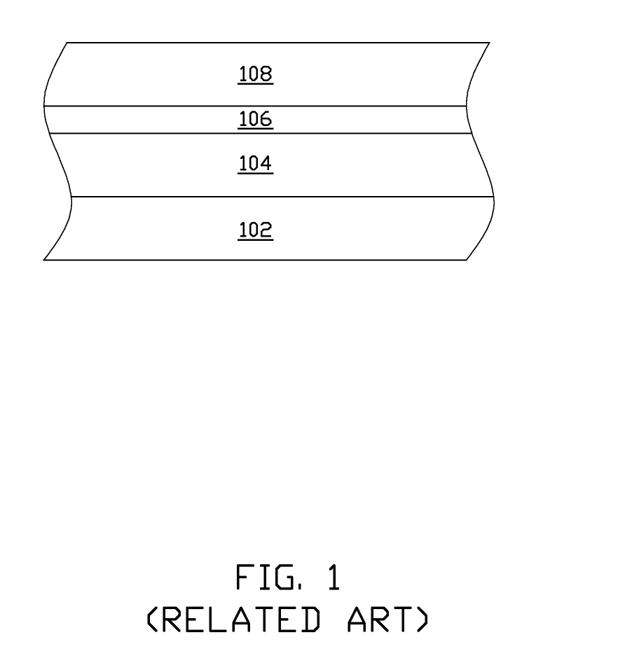

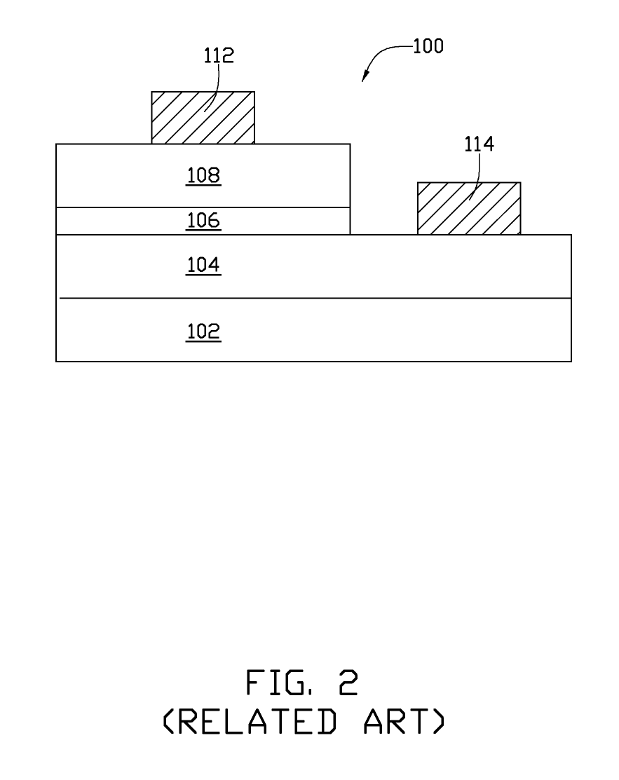

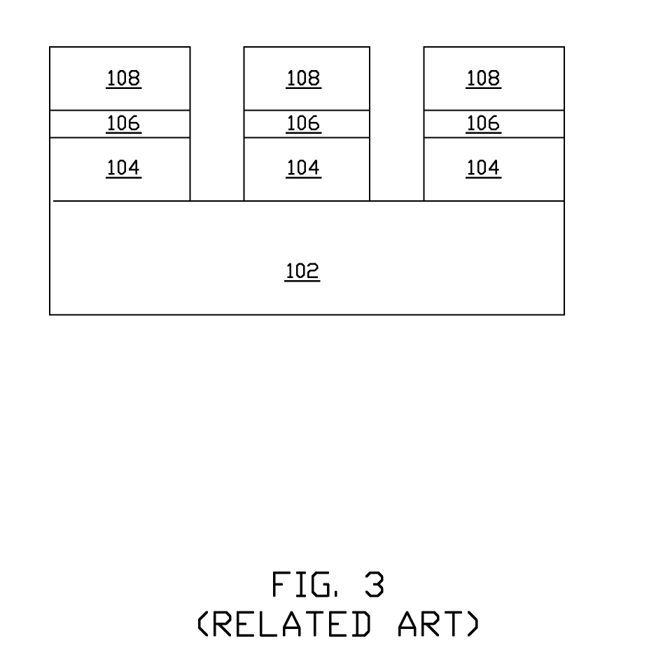

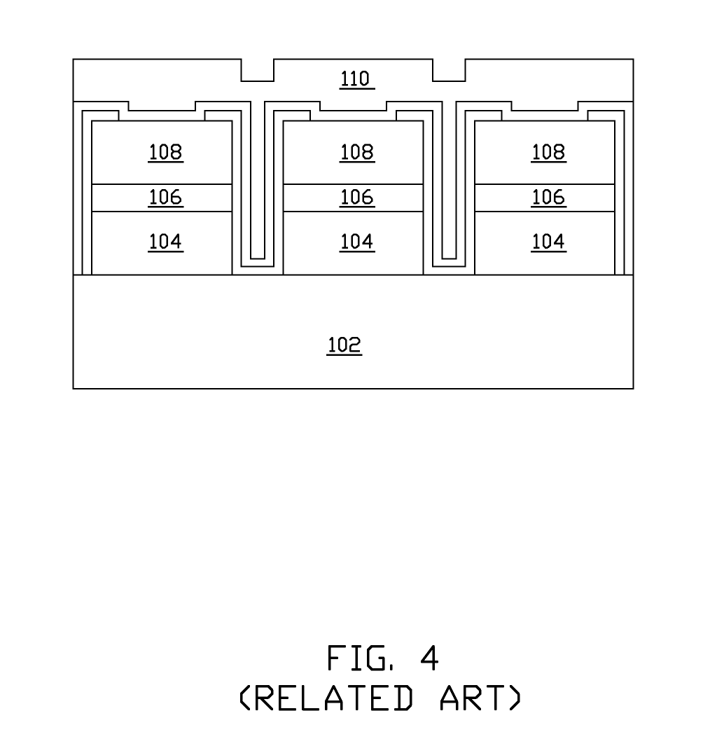

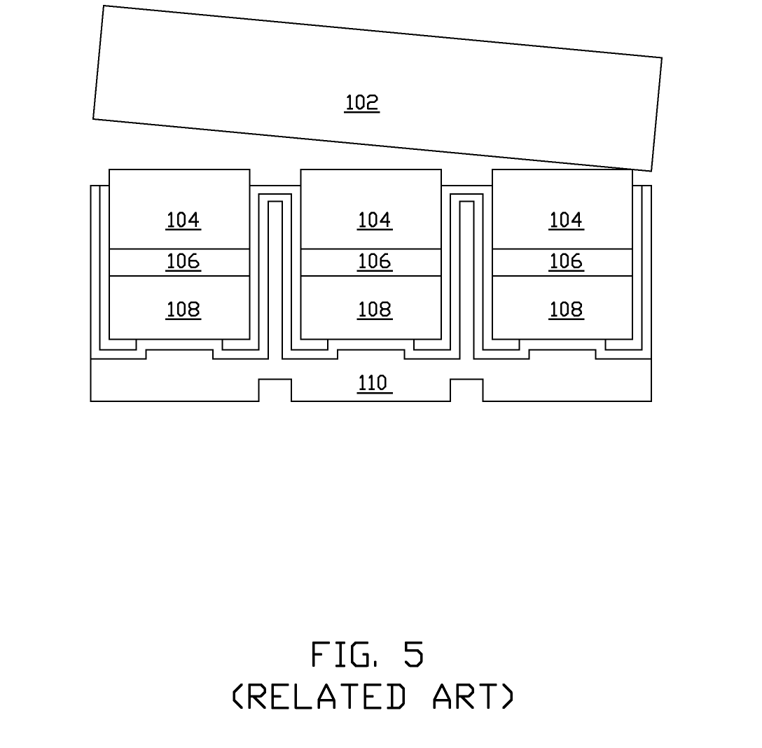

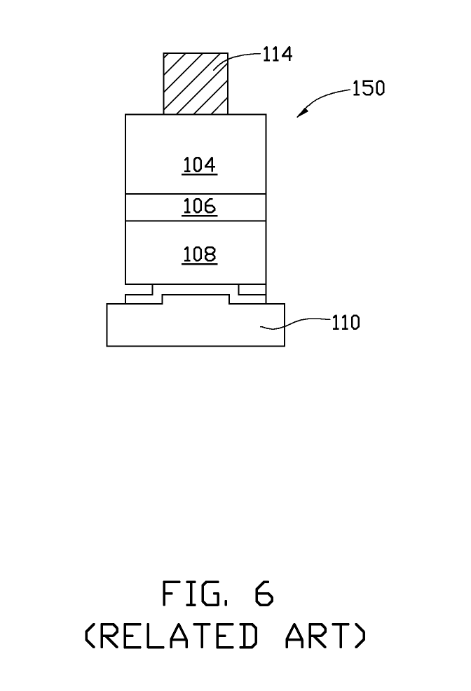

### DETAILED DESCRIPTION

Embodiments of a light emitting diode and manufacturing process thereof as disclosed are described in detail here with reference to the drawings.

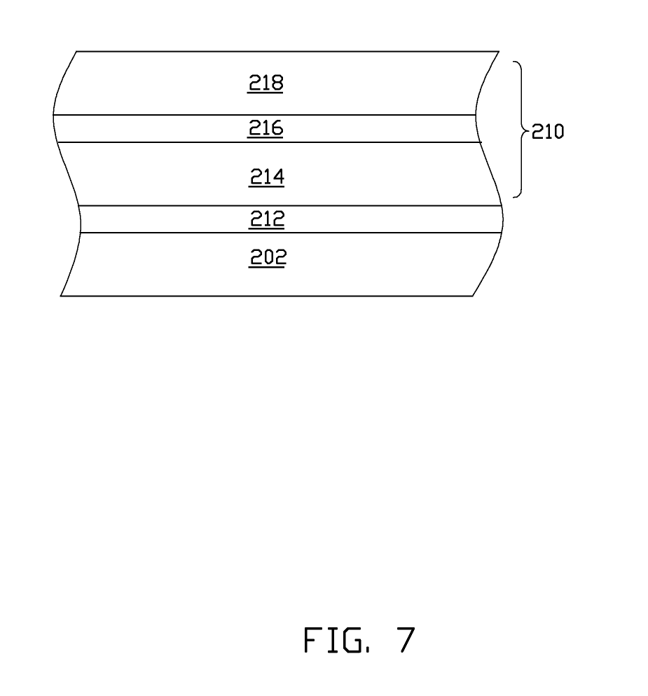

FIGS. 7-10 are schematic views of a vertical cross section of a light emitting diode in accordance with a first embodiment and its semi-finished products at different manufacturing processes. As shown in FIG. 7, a temporary substrate 202 is provided, of material matching the lattice of epitaxial layer, such as sapphire, silicon carbide, or gallium arsenide. In this embodiment, the temporary substrate 202 is sapphire. A buffer layer 212, an n-type semiconductor layer 214, an active layer 216, and a p-type semiconductor layer 218 are sequentially formed on the temporary substrate 202. The n-type semiconductor layer 214, the active layer 216, and the p-type semiconductor layer 218 define an epitaxial multi-layer 210.

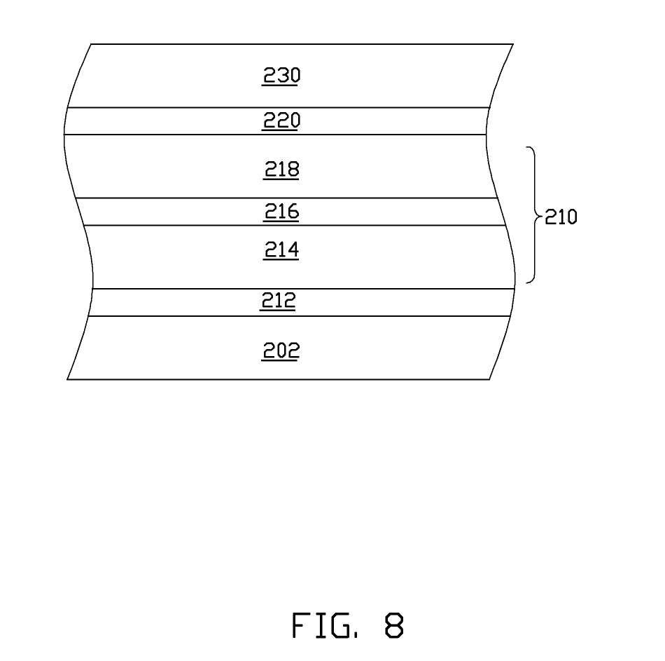

Referring to FIG. 8, a contact layer 220 is formed on the epitaxial multi-layer 210. The contact layer 220 includes transparent conductive material such as nickel, gold, aluminum, silver, platinum, palladium, chromium, indium tin oxide, indium zinc oxide, or an alloy thereof. A carrier substrate 230 is formed on the contact layer 220 by vapor deposition, sputtering, electrolytic deposition, or electrodeless plating. The carrier substrate 230 mainly contains copper, nickel, cobalt, or an alloy thereof.

The CTE is 16.5 ppm/k of copper, 13.3 ppm/k of nickel, 13.36 ppm/k of cobalt, and are all relatively very large. The carrier substrate 230 is metal and doped with a medium having less CTE, such as diamond particle, diamond-like carbon particle, silicon oxide particle, silicon nitride particle, strontium titanate particle, yttrium aluminum garnet particle, zirconium oxide particle, or silicon carbide particle. A ratio of the metal material to the medium in volume is between 0.1:1 and 1:1.

For example, if the diamond particle has CTE of 1.1 ppm/k and thermal conductivity 4 fold as the copper, in this embodiment, the ratio of the metal material (copper) and the medium (diamond particle) is 4:6 for the carrier substrate 230 to improve the thermal conduction and modulate the CTE. The diamond particle can also improve the hardness for support and the thickness of the carrier substrate 230 can be reduced from 100 μm to 70 μm. The cost of process of the carrier substrate 230 is also reduced significantly.

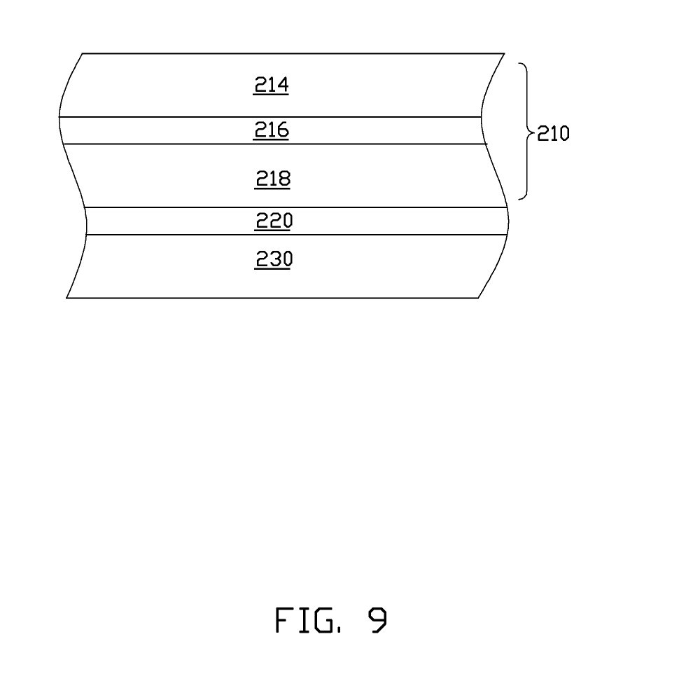

Referring to FIG. 9, the temporary substrate 202 and the buffer layer 212 are turned over and removed by polishing, chemical etching, or Laser lift-off to expose the n-type semiconductor layer 214 of the epitaxial multi-layer 210.

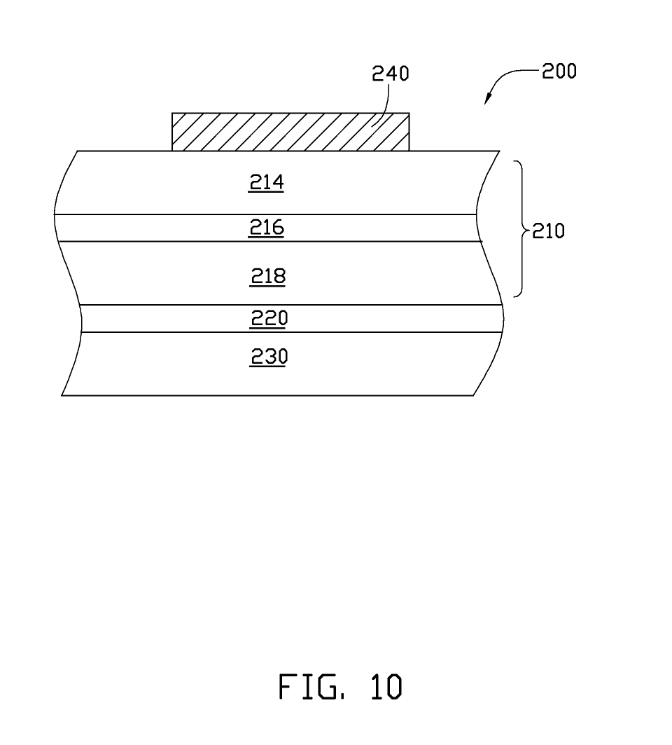

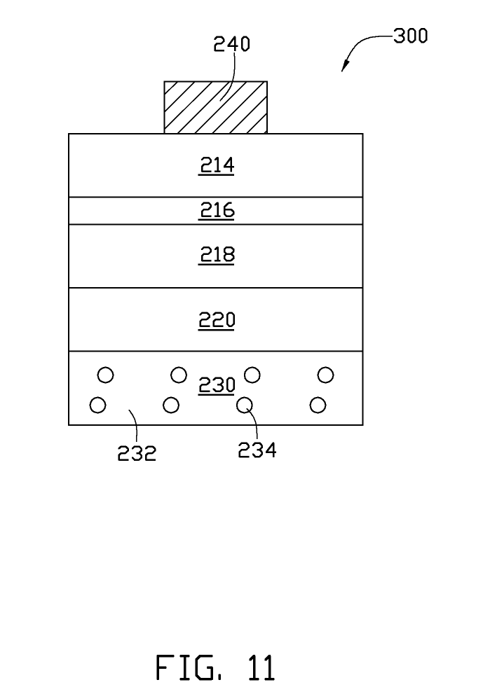

As shown in FIG. 10, an electrode 240 is formed on the n-type semiconductor layer 214. The electrode 240 is the same as the contact layer 220 comprising a transparent conductive layer of nickel, gold, aluminum, silver, platinum, palladium, chromium, indium tin oxide, indium zinc oxide, or an alloy thereof. The thickness of the carrier substrate 230 is less than 70 μm in this embodiment and is more easily cut. As shown in FIG. 11, a light emitting diode 300 in accordance with a first embodiment comprises a carrier substrate 230 including a metal material 232 and a medium 234, a contact layer 220, a p-type semiconductor layer 218, an active layer 216, an n-type semiconductor layer 214, and an electrode 240. In this embodiment, the contact layer 220 and the electrode 240 are the contacting electrodes of the light emitting diode 300.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode comprising:
a carrier substrate including a metal material and a medium; and
an epitaxial multi-layer on the carrier substrate, wherein a coefficient of thermal expansion of the medium is less than that of the metal material.

2. The light emitting diode as claimed in claim 1, wherein the metal material is copper, nickel, cobalt, or an alloy thereof.

3. The light emitting diode as claimed in claim 1, wherein the medium is diamond particle, diamond-like carbon particle, silicon oxide particle, silicon nitride particle, strontium titanate particle, yttrium aluminum garnet particle, zirconium oxide particle, or silicon carbide particle.

4. The light emitting diode as claimed in claim 1, wherein the coefficient of thermal expansion of the medium is less than 5 ppm/k.

5. The light emitting diode as claimed in claim 1, wherein a ratio of the metal material to the medium in volume is between 0.1:1 and 1:1.

6. The light emitting diode as claimed in claim 1, wherein a thickness of the carrier substrate is less than 70 μm.

7. The light emitting diode as claimed in claim 1 further comprising a contact layer between the carrier substrate and the epitaxial multi-layer.

8. The light emitting diode as claimed in claim 7 further comprising an electrode on another side of the epitaxial multi-layer opposite to the contact layer.

9. The light emitting diode as claimed in claim 8, wherein the contact layer and the electrode respectively comprise a transparent metal layer.

10. The light emitting diode as claimed in claim 9, wherein the contact layer and the electrode are respectively nickel, gold, aluminum, silver, platinum, palladium, chromium, indium tin oxide, indium zinc oxide, or an alloy thereof.

11. A manufacturing method of a light emitting diode, the method comprising:
providing a temporary substrate;
forming an epitaxial multi-layer on the temporary substrate;
forming a carrier substrate on the epitaxial multi-layer, the carrier substrate comprising metal material and a medium, wherein a coefficient of thermal expansion of the medium is less than that of the metal material; and
executing a lift-off process to separate the temporary substrate from the epitaxial multi-layer.

12. The manufacturing method of light emitting diode as claimed in claim 11, wherein a thickness of the carrier substrate is less than 70 μm.

13. The manufacturing method of light emitting diode as claimed in claim 11, wherein the metal material is copper, nickel, cobalt, or an alloy thereof.

14. The manufacturing method of light emitting diode as claimed in claim 11, wherein the medium is diamond particle, diamond-like carbon particle, silicon oxide particle, silicon nitride particle, strontium titanate particle, yttrium aluminum garnet particle, zirconium oxide particle, or silicon carbide particle.

15. The manufacturing method of light emitting diode as claimed in claim 11, wherein the coefficient of thermal expansion of the medium is less than 5 ppm/k.

16. The manufacturing method of light emitting diode as claimed in claim 11, wherein a ratio of the metal material to the medium in volume is between 0.1:1 and 1:1.

17. The manufacturing method of light emitting diode as claimed in claim 11 further comprising a process of forming a contact layer on the epitaxial multi-layer before forming the carrier substrate.

18. The manufacturing method of light emitting diode as claimed in claim 17 further comprising a process of forming an electrode on a side of the epitaxial multi-layer opposite to the contact layer after executing the lift-off process of the temporary substrate.

19. The manufacturing method of light emitting diode as claimed in claim 18, wherein the contact layer and the electrode respectively comprise a transparent metal layer.

20. The manufacturing method of light emitting diode as claimed in claim 19, wherein the contact layer and the electrode are respectively nickel, gold, aluminum, silver, platinum, palladium, chromium, indium tin oxide, indium zinc oxide, or an alloy thereof.
